(19) United States
(12) Patent Application Publication
(10) Pub. No.: US 2010/0203696 A1
(43) Pub. Date: Aug. 12, 2010

(54) SEMICONDUCTOR DEVICE AND METHOD FOR MANUFACTURING THE SAME

(75) Inventor: Seon Yong CHA, Chungcheongbuk-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/764,863

(22) Filed: Apr. 21, 2010

Related U.S. Application Data
(62) Division of application No. 11/852,926, filed on Sep. 10, 2007.

(30) Foreign Application Priority Data
May 22, 2007 (KR) 10-2007-0049656

(51) Int. Cl. H01L 21/336

(52) U.S. Cl. 438/270; 257/E21.41

(57) ABSTRACT

A semiconductor device and a method for manufacturing the same are disclosed. The semiconductor device suitable for preventing a threshold voltage of a recess gate from decreasing due to a voltage of an adjacent storage node comprises a semiconductor substrate having an active region which includes a gate area and a storage node contact area and is recess in the gate area; a device isolation structure formed in the semiconductor substrate to define the active region and having a shield layer therein; a recess gate formed in the gate area of the semiconductor substrate; and a storage node formed to be connected with the storage node contact area of the active region.

### CROSS-REFERENCE TO RELATED APPLICATIONS

The present application claims priority to Korean patent application number 10-2007-0049656, filed on May 22, 2007, which is incorporated herein by reference in its entirety.

### BACKGROUND OF THE INVENTION

The present invention relates to a semiconductor device and a method for manufacturing the same, and more particularly, to a semiconductor device which can secure a threshold voltage margin, thereby increasing a manufacturing yield, and a method for manufacturing the same.

With high integration of a semiconductor device and as the channel length of a transistor decreases, a short channel effect, in which a threshold voltage abruptly decreases, is induced.

In this situation, methods for realizing semiconductor devices having variously shaped recess channels have been disclosed in the art. By manufacturing a semiconductor device having a recess channel, an increase in channel length is obtained. Some of the benefits of such are that the doping concentration of a substrate can be reduced, and a drain-induced barrier lowering (DIBL) characteristic can be improved.

Hereafter, a conventional method for manufacturing a semiconductor device having a recess channel will be simply described.

In a semiconductor substrate which has an active region including a gate forming area and a device isolation region, a device isolation structure, which defines the active region, is formed in the device isolation region. A mask pattern is formed on the semiconductor substrate which is formed with the device isolation structure, to expose the gate forming area of the active region.

By etching the portion of the substrate which is exposed through the mask pattern, a groove for a gate is defined in the gate forming area of the active region. After removing the mask pattern, a gate insulation layer is formed on the surface of the semiconductor substrate including the groove for a gate.

A gate conductive layer and a hard mask layer are formed on the gate insulation layer to fill the groove for a gate. By pattering the hard mask layer, the gate conductive layer and the gate insulation layer, a gate having a recess channel is formed in and on the groove for a gate.

Spacer layers are formed on both sidewalls of the gate. By implementing ion-implantation into the substrate on both sides of the gate, a source area and a drain area are formed. A storage node contact is formed on the source area, and a bit-line contact plug is formed on the drain area.

Thereafter, by sequentially conducting a series of well-known subsequent processes, a semiconductor device having a recess channel is completed.

However, in the conventional art as described above, since the voltage applied to a storage node influences the channel portion which corresponds to the lower portion of the gate, by way of an adjacent device isolation structure, a threshold voltage is decreased. The decrease of the threshold voltage is worsened with high integration of a semiconductor device. As a result, the threshold voltage margin of a cell transistor is decreased and a manufacturing yield decreases.

### SUMMARY OF THE INVENTION

An embodiment of the present invention is directed to a semiconductor device which can secure a threshold voltage margin and a method for manufacturing the same.

Another embodiment of the present invention is directed to a semiconductor device which can increase a manufacturing yield and a method for manufacturing the same.

In one aspect, a semiconductor device is suitable for preventing a threshold voltage of a gate from decreasing due to a voltage of an adjacent storage node. The device comprises a semiconductor substrate defining an active region and a device isolation region, the device isolation region defining the active region, the active region including a gate area and a storage node contact area; a device isolation structure formed in the semiconductor substrate to define the active region and having a shield layer within the device isolation structure; a gate formed in the gate area of the semiconductor substrate; a storage node contact plug electrically coupled to a doped region assigned to the gate; and a storage node electrically coupled to the storage node contact plug, the storage node being configured to cooperate with the gate and store information.

In one aspect, a method for manufacturing a semiconductor device suitable for preventing a threshold voltage of a gate from decreasing due to a voltage of an adjacent storage node is disclosed. The method comprises providing a semiconductor substrate having an active region and an isolation region, the isolation region defining the active region; forming a device isolation structure in the isolation region, the device isolation structure including a shield layer and a dielectric layer surrounding the shield layer; forming a gate and first and second doped regions in the active region, the first and second doped regions being assigned to the gate; and forming a storage node in the active region, the storage node being adjacent to the gate and being configured to cooperate with the gate to store information.

In one aspect, a semiconductor device suitable for preventing a threshold voltage of a recess gate from decreasing due to a voltage of an adjacent storage node comprises a semiconductor substrate having an active region which includes a gate area and a storage node contact area and is recess in the gate area; a device isolation structure formed in the semiconductor substrate to delimit the active region and having a shield layer formed therein; a recess gate formed in the gate area of the semiconductor substrate; and a storage node formed to be connected with the storage node contact area of the active region.

The device isolation structure comprises a trench defined in a device isolation region of the semiconductor substrate; a first insulation layer formed on bottom and side surfaces of the trench; the shield layer formed on the first insulation layer; and a second insulation layer formed on the shield layer to fill the trench.

The first insulation layer is formed on the bottom surface of the trench. The first insulation layer comprises a layer having excellent flowability, which is made of an SOD (spin-on dielectric) layer or an SOG (spin-on glass) layer, and a layer having excellent step coverage, which is made of an HDP (high density plasma) layer or an ALD (atomic layer deposition) layer.

The shield layer is made of a polysilicon layer.

The polysilicon layer comprises an N-type polysilicon layer.

The shield layer is positioned at ¼˜¾ of a depth of the device isolation structure.

The shield layer has a thickness which corresponds to ¼˜½ of a thickness of the device isolation structure.

The shield layer is integrally connected throughout the overall device isolation region of the semiconductor substrate.

The shield layer is applied with a ground voltage of 0V from the outside.

In another embodiment, a method for manufacturing a semiconductor device suitable for preventing a threshold voltage of a recess gate from decreasing due to a voltage of an adjacent storage node comprises the steps of forming a device isolation structure which has a shield layer therein, in a device isolation region of a semiconductor substrate which has an active region including a gate area and a storage node contact area and the device isolation region; forming a recess gate in the gate area; and forming a storage node in the active region to be connected with the storage node contact area.

The step of forming the device isolation structure comprises the steps of defining a trench by etching the device isolation region of the semiconductor substrate; forming a first insulation layer on bottom and side surfaces of the trench; forming the shield layer on the first insulation layer; and forming a second insulation layer on the shield layer and the first insulation layer to fill the trench.

The step of forming the first insulation layer comprises the steps of forming a layer having excellent flowability on the bottom surface of the trench in an SOD type or an SOG type; and forming a layer having excellent step coverage on the layer having excellent flowability and the side surfaces of the trench in an HDP type or an ALD type.

After the step of forming the layer having excellent step coverage, the method further comprises the step of etching the layer having excellent step coverage to expose the layer having excellent flowability which is formed on the bottom surface of the trench.

The step of forming the shield layer comprises the steps of depositing the shield layer on the first insulation layer; and etching the shield layer to allow the shield layer to have a thickness which does not completely fill the trench.

The shield layer is made of a polysilicon layer.

The polysilicon layer comprises an N-type polysilicon layer.

The shield layer is positioned at ¼˜¾ of a depth of the device isolation structure.

The shield layer is formed to have a thickness which corresponds to ¼˜½ of a thickness of the device isolation structure.

The shield layer is formed to be integrally connected throughout the overall device isolation region of the semiconductor substrate.

The shield layer is applied with a ground voltage of 0V from the outside.

### BRIEF DESCRIPTION OF THE DRAWINGS

FIG. 1 is a plan view illustrating a semiconductor device in accordance with an embodiment of the present invention.

FIG. 2 is a cross-sectional view taken along the line A-A′ of FIG. 1.

FIGS. 3A through 3H are cross-sectional views that illustrate the processes associated with a method for manufacturing a semiconductor device in accordance with one embodiment of the present invention.

FIG. 4 is a plan view illustrating a shield layer formed in the semiconductor device.

### DESCRIPTION OF SPECIFIC EMBODIMENTS

In one embodiment of the present invention, a device isolation structure, which defines active regions and have a shield layer therein, is formed in the device isolation region of a semiconductor substrate. The shield layer is made of an N-type polysilicon layer and is formed to be integrally connected throughout the overall device isolation structure in the cell region of the semiconductor substrate.

By applying a ground voltage of 0V to the integrally connected shield layer, the shield layer formed in the device isolation structure functions to block the electric fields produced in adjacent cells from one another.

Therefore, it is possible to prevent the voltage of an adjacent storage node from influencing the channel portion of an adjacent recess gate through the device isolation structure and thereby the threshold voltage margin of the gate from decreasing. Through this, the manufacturing yield of a semiconductor device can be increased.

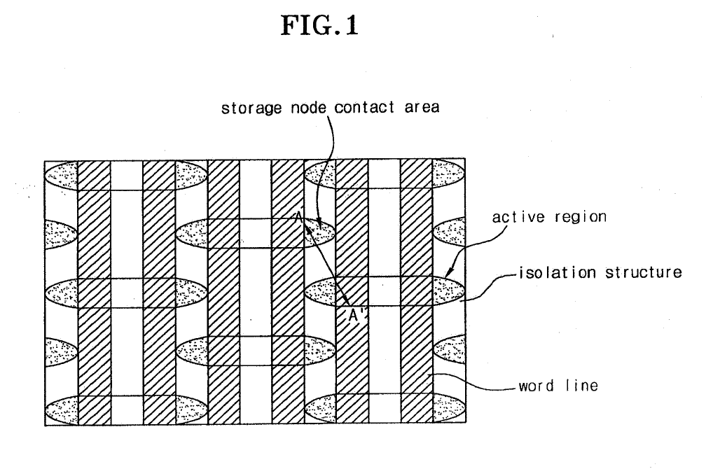

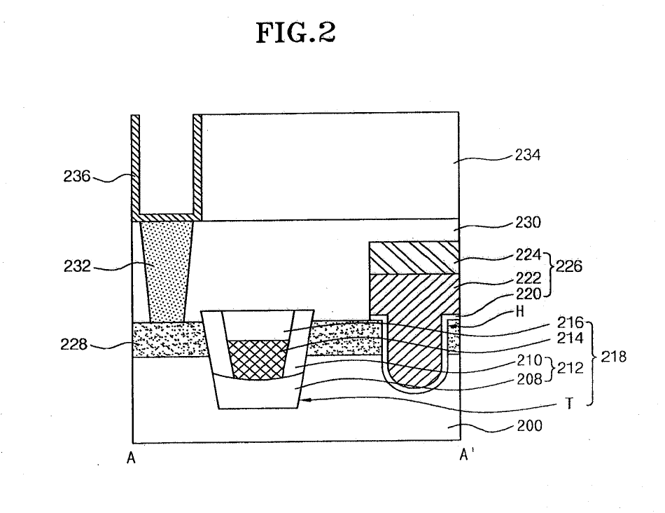

FIG. 1 is a plan view illustrating a semiconductor device in accordance with an embodiment of the present invention, and FIG. 2 is a cross-sectional view taken along the line A-A′ of FIG. 1. In FIG. 1, a device isolation structure has a shield layer (see FIG. 2) therein.

Referring to FIG. 2, a device isolation structure 218, which defines an active region, has a shield layer 214 formed therein. The structure 218 is formed in a semiconductor substrate 200 which includes a gate area and a storage node contact area. The shield layer 214 comprises a conductive material, e.g., polysilicon. In the present embodiment, the gate area is recessed, but the present invention may be implemented on a device that does not use a recessed gate.

A recess gate 226 is formed in the gate area of the semiconductor substrate 200, junction areas 228 are formed in the semiconductor substrate 200 on two opposing sides of the recess gate 226, and a first interlayer dielectric 230 is formed on the resultant substrate 200 to cover the recess gate 226.

A storage node contact plug 232, which is brought into contact with the source area of the junction areas 228, is formed in the first interlayer dielectric 230. A second interlayer dielectric 234 is formed on the first interlayer dielectric 230 including the storage node contact 232. A storage node 236, which contacts the storage node contact 232, is formed in the second interlayer dielectric 234. The storage node 236 is defines a lower plate of a capacitor to be formed.

The device isolation structure 218 comprises a trench T which is defined in the device isolation region of the semiconductor substrate 200, a first insulation layer 212 which is formed on the bottom and side surfaces of the trench T, the shield layer 214 which is formed on the first insulation layer 212, and a second insulation layer 216 which is formed on the shield layer 214 to fill the trench T.

The first insulation layer 212 is composed of a bottom layer 208 and a sidewall layer 210. The bottom layer 208 has good flowability and is formed on the bottom surface of the trench T. The sidewall layer 210 has good step coverage and is formed on the side surfaces of the trench T. The layer 208 comprises a layer which is formed in a spin-on dielectric (SOD) method or a spin-on glass (SOG) method (hereinafter, the layer 208 may be referred to as an “SOD layer” or “SOG layer”). The layer 210 having good step coverage comprises a layer which is formed in a high density plasma (HDP) deposition method or a an atomic layer deposition (ALD) method (hereinafter, the layer 210 may be referred to as an “HDP layer” or “ALD layer”). The second insulation layer 216 is composed of any one of an HDP layer, an SOD layer and an SOG layer.

The shield layer 214 is made of a polysilicon layer, preferably, an N-type polysilicon layer, in the present embodiment. Another conductive material may be used in a different embodiment, e.g., tungsten. The shield layer 214 is positioned at ¼˜¾ of the depth of the device isolation structure 218, and has a thickness which corresponds to ¼˜½ of the thickness of the device isolation structure 218. In the present embodiment, the shield layer 214 is formed to be integrally connected throughout the overall device isolation region of the semiconductor substrate 200.

In the semiconductor device according to the present embodiment as described above, it is possible to prevent the voltage of the storage node 236 which is adjacent to the device isolation structure 218 from influencing the channel portion of the recess gate 226 by applying a ground voltage of 0V to the shield layer 214 which is formed in the device isolation structure 218.

Accordingly, in the present embodiment, it is possible to prevent the threshold voltage of the recess gate 226 from decreasing and thereby the threshold voltage margin of the recess gate 226 from decreasing. Through this, a manufacturing yield of a semiconductor device can be increased.

In FIG. 2, a reference symbol H designates a groove. Reference numerals 220, 222, and 224 designate a gate insulation layer, a gate conductive layer, and a hard mask layer, respectively.

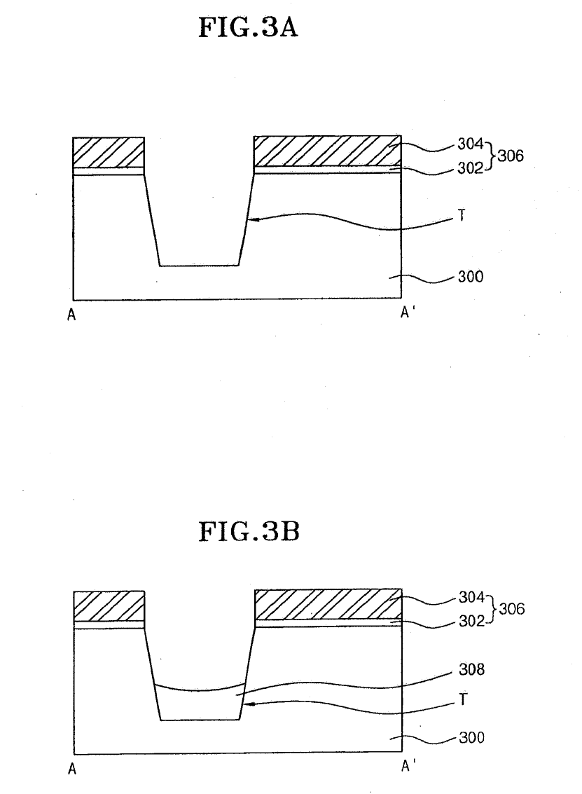

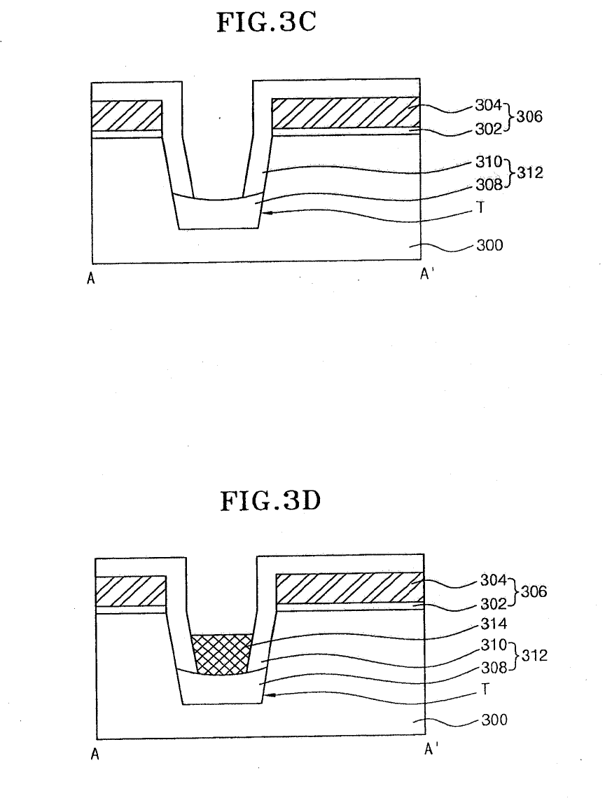

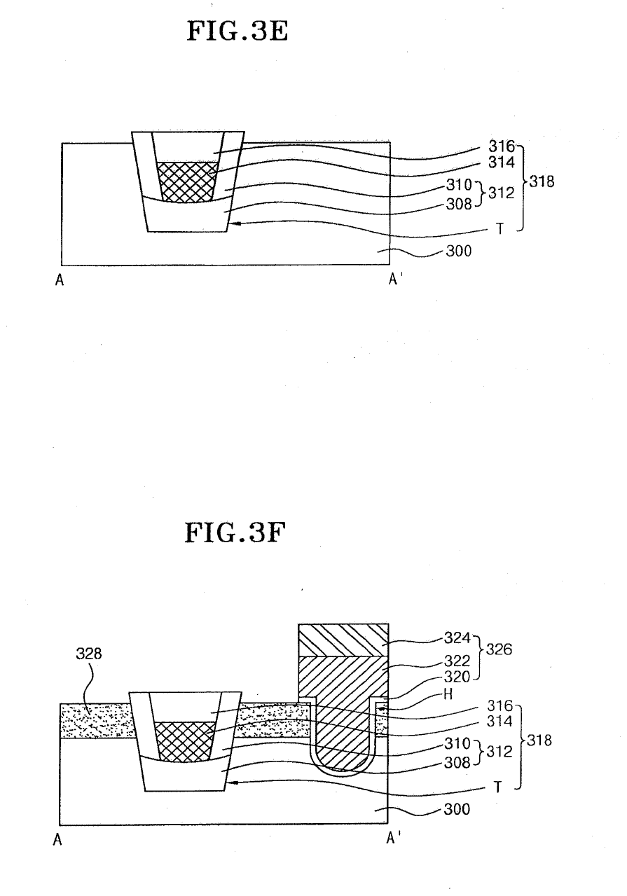

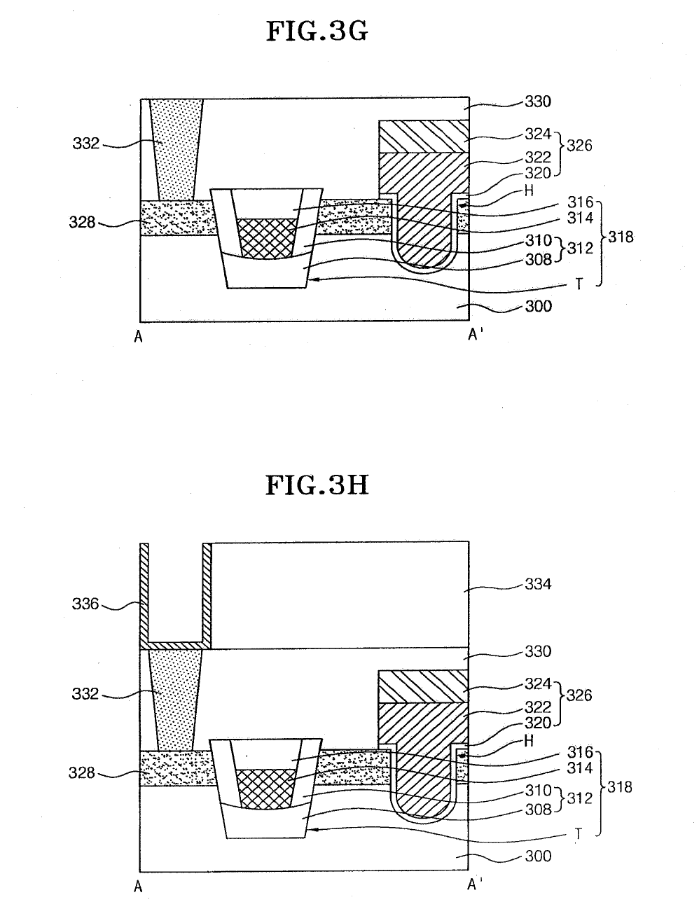

FIGS. 3A through 3H are cross-sectional views illustrating processes associated with a method for manufacturing a semiconductor device in accordance with one embodiment of the present invention.

Referring to FIG. 3A, a hard mask 306 is formed on a semiconductor substrate 300 which has an active region including a gate forming area and a storage node contact area and a device isolation region, to expose the device isolation region. The hard mask 306 includes a pad oxide layer 302 and a pad nitride layer 304. By etching the portion of the semiconductor substrate 300 which is exposed through the hard mask 306, a trench T is defined in the device isolation region.

Referring to FIG. 3B, after a layer 308 having good flowability is deposited on the resultant substrate 300 which is defined with the trench T. The layer 308 is etched such that the layer 308 remains only on the bottom surface of the trench T. The layer 308 may be formed using an SOD or SOG method, i.e., may be an SOD layer or an SOG layer.

Referring to FIG. 3C, a layer 310 having good step coverage is formed on the overall surface of the substrate 300 including the layer 308. The layer 310 may be formed using an HDP or ALD method, i.e., may be an HDP layer or an ALD layer. The layer 310 is etched, e.g., anisotropically, to expose the layer 308 formed on the bottom surface of the trench T. A first insulation layer 312 is formed such that it is formed on the bottom and side surfaces of the trench T and is composed of the layer 308 having good flowability and the layer 310 having good step coverage.

The first insulation layer 312 is formed such that a subsequently formed shield layer 314 can be positioned in the middle of the trench T. Although the first insulation layer 312 is formed using two different deposition method in the present embodiment, it may be formed using a single deposition method in another embodiment.

Referring to FIG. 3D, a polysilicon layer, preferably, an N-type is polysilicon layer is deposited on the first insulation layer 312 composed of the layer 308 and the layer 310 to fill the trench T. By selectively etching the polysilicon layer, the shield layer 314 is formed to be positioned in the middle, for example, ¼˜¾ of the trench T. The shield layer 314 is formed to have a thickness which corresponds to ¼˜½ of the depth of the trench T and to be integrally connected throughout the overall device isolation region of the semiconductor substrate 300 in the present embodiment.

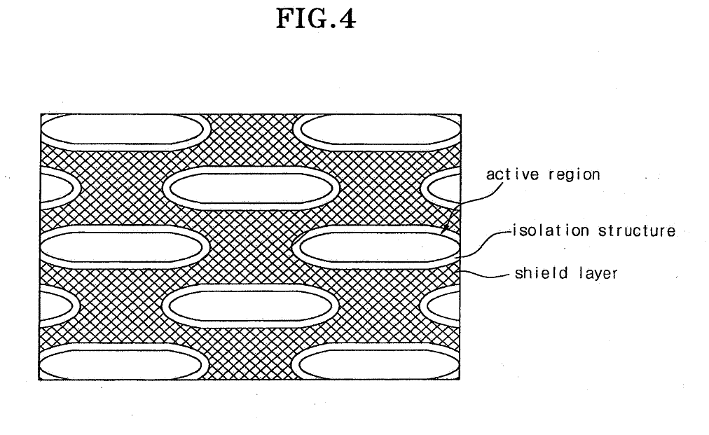

FIG. 4 is a plan view illustrating a shield layer formed in the semiconductor device according to one embodiment. The semiconductor device is delayered to show the shield layer. As can be readily seen from the drawing, the shield layer 314 is formed to be integrally connected throughout the overall device isolation region of the semiconductor substrate 300. Due to this fact, by applying a ground voltage of 0V to the shield layer 314, it is possible to prevent the voltage of an adjacent storage node from influencing the channel portion of a recess gate.

Referring to FIG. 3E, a second insulation layer 316 is formed on the resultant semiconductor substrate 300 which is formed with the shield layer 314, to fill the trench T. The second insulation layer 316 is made of any one of an HDP layer, an SOD layer and an SOG layer. After planarizing the first insulation layer 312 and the second insulation layer 316 until the hard mask 306 is exposed, by removing the hard mask 306, a device isolation structure 318, which defines the active region and has the shield layer 314 formed therein, is completed.

Referring to FIG. 3F, after defining a groove H for a gate by recessing the gate forming area of the active region of the semiconductor substrate 300, a recess gate 326, which is composed of a gate insulation layer 320, a gate conductive layer 322 and a hard mask layer 324, is formed in and on the groove H. Junction areas 328 such as a source area and a drain area are formed in the substrate 300 on opposing sides of the recess gate 326 through an ion implantation process.

Referring to FIG. 3G, a first interlayer dielectric 330 is deposited on the overall surface of the substrate 300 including the recess gate 326 and the junction areas 328 to cover the recess gate 326. A storage node contact plug 332, which is brought into contact with the source area of the junction areas 328, is formed in the first interlayer dielectric 330.

Referring to FIG. 3H, after forming a second interlayer dielectric 334 on the first interlayer dielectric 330 which is formed with the storage node contact plug 332, by etching the second interlayer dielectric 334, a contact hole (not shown) is defined to expose the storage node contact plug 332. By depositing a conductive layer on the surface of the contact hole, a storage node 336, which is brought into contact with the storage node contact plug 332, is formed.

Thereafter, while not shown in the drawings, by sequentially conducting a series of well-known subsequent processes, the semiconductor device according to the present invention is completed.

As is apparent from the above description, in the present invention, since a shield layer made of a polysilicon layer is formed in a device isolation structure, it is possible to prevent the threshold voltage of a recess gate from decreasing due to the voltage of a storage node adjacent to the device isolation structure, and through this, it is possible to prevent the threshold voltage margin of the recess gate from decreasing.

Therefore, by applying a ground voltage of 0V to the shield layer which is formed to be integrally connected throughout the device isolation structure of a semiconductor substrate, because it is possible to reduce the influence of the voltage of the adjacent storage node on the recess gate, the threshold voltage of the recess gate is prevented from decreasing, whereby a threshold voltage margin can be secured.

Accordingly, in the present invention, a cell can operate without noise irrespective of the voltage of the adjacent storage node. Since a constant threshold voltage level can be maintained without experiencing field effect by the adjacent storage node, the manufacturing yield of a semiconductor device can be increased.

Although a specific embodiment of the present invention has been described for illustrative purposes, those skilled in the art will appreciate that various modifications, additions and substitutions are possible, without departing from the scope and the spirit of the invention as disclosed in the accompanying claims.

1.-13. (canceled)

14. A method for manufacturing a semiconductor device suitable for preventing a threshold voltage of a gate from decreasing due to a voltage of an adjacent storage node, the method comprising:
providing a semiconductor substrate having an active region and an isolation region, the isolation region defining the active region;
forming a device isolation structure in the isolation region, the device isolation structure including a shield layer and a dielectric layer surrounding the shield layer, wherein the dielectric layer includes a bottom layer formed using a first deposition method and a sidewall layer formed using a second deposition method, and the first and second deposition methods are different methods;
forming a gate and first and second doped regions in the active region, the first and second doped regions being assigned to the gate; and
forming a storage node in the active region, the storage node being adjacent to the gate and being configured to cooperate with the gate to store information.

15. The method according to claim 14, wherein the step of forming the device isolation structure comprises:
defining a trench in the semiconductor substrate;
forming a bottom layer and a sidewall layer within the trench;
forming the shield layer in the trench and over the bottom layer; and
forming a top layer on the shield layer to fill the trench.

16. The method according to claim 15, wherein the bottom layer and the sidewall layer are formed using different deposition methods.

17. The method of claim 16, wherein the bottom layer is formed using a spin-on dielectric method or spin-on glass method, and the sidewall layer is formed using a high density plasma method or an atomic layer deposition method.

18. The method according to claim 15, wherein the bottom layer is formed before the sidewall layer, the method further comprises etching the sidewall layer to expose the bottom layer.

19. The method according to claim 15, wherein the step of forming the shield layer comprises:
depositing the shield layer on the bottom layer; and
etching the shield layer to ensure that an upper portion of the trench is not filled by the shield layer.

20. The method according to claim 19, wherein the shield layer includes a polysilicon layer.

21. The method according to claim 20, wherein the polysilicon layer comprises an N-type polysilicon layer.

22. The method according to claim 14, wherein the shield layer is formed to be integrally connected throughout the isolation region of the semiconductor substrate.

23. The method according to claim 14, wherein the shield layer is applied with a voltage of 0V.

24. The method according to claim 15, wherein the shield layer is formed to be positioned in the ¼˜¾ of the trench.

25. The method according to claim 15, wherein the shield layer is formed to have a thickness which corresponds to ¼˜½ of the depth of the trench.

26. The method according to claim 14, wherein the gate comprising a recessed gate.
